(19) United States
(12) Patent Application Publication
(10) Pub. No.: US 2012/0167972 A1
(43) Pub. Date: Jul. 5, 2012

(54) ORGANIC PHOTOVOLTAIC CELL

(75) Inventors: Hsin-Rong Tseng, Tainan City (TW); Chun-Liang Lin, New Taipei City (TW)

(73) Assignee: AU OPTRONICS CORPORATION, Hsinchu (TW)

(21) Appl. No.: 13/073,977

(22) Filed: Mar. 28, 2011

(30) Foreign Application Priority Data
Dec. 30, 2010 (TW) 99146922

(51) Int. Cl. H01L 31/0224; H01L 31/0232

(52) U.S. Cl. 136/256; 136/259

(57) ABSTRACT

An organic photovoltaic cell is provided, which includes an organic active layer, a light-transmissive electrode, a reflective electrode, and an optical film. The light-transmissive electrode and the reflective electrode are respectively disposed at two opposite sides of the organic active layer. The optical film and the organic active layer are respectively disposed at two opposite sides of the light-transmissive electrode. The optical film has an inner surface and an outer surface opposite to the inner surface. The transmittance of the optical film is higher than 90% when light enters the optical film from the outer surface. The reflectivity of the inner surface is higher than 10% when the light enters the optical film from the inner surface. The haze of the optical film is higher than 90%.

### CROSS-REFERENCE TO RELATED APPLICATION

This application claims the priority benefit of Taiwan application serial no. 99146922, filed Dec. 30, 2010. The entirety of the above-mentioned patent application is hereby incorporated by reference herein and made a part of this specification.

### TECHNICAL FIELD

The disclosure relates to a photovoltaic cell, and more particularly to an Organic Photovoltaic (OPV) cell having high photoelectric conversion efficiency.

### BACKGROUND

Solar energy is a clean, pollution-free, and inexhaustible energy, and has been the focus of most attention in solving the pollution and shortage problem that the fossil energy faces currently. Since solar cells can directly convert the solar energy into electricity, the solar cells become one of the important research subjects in the industry at present.

A silicon-based solar cell and the OPV cell are a common photovoltaic cell in the industry at present. By taking the OPV cell as an example, since the carrier mobility of an organic material is low (being about 10⁻⁴-10⁻³ cm²/Vs), the thickness of an active layer of the OPV cell is not suggested to be too large; otherwise, a carrier may be re-combined after being excited by light, such that the photoelectric conversion efficiency is reduced. In accordance with the characteristics of the OPV cell, although the light absorption efficiency and short circuit current (Jsc) may be increased by increasing the thickness of the active layer, and an overall resistance is increased, which results in decrease of a fill factor. On the contrary, the fill factor may be increased by decreasing the thickness of the active layer, but the light absorption efficiency and the short circuit current may also be reduced.

In view of the above, it is difficult to improve the photoelectric conversion efficiency and the electric property (such as resistance and fill factor) of the OPV cell simultaneously by merely adjusting the thickness of the active layer. Therefore, how to improve the photoelectric conversion efficiency and the electric property of the OPV cell is an important issue in the industry at present.

### SUMMARY

Accordingly, the present invention provides to an OPV cell to effectively improve the photoelectric conversion efficiency and the electric property through attachment of an optical film.

The present invention provides an OPV cell for converting light into electricity. The OPV cell includes an organic active layer, a light-transmissive electrode, a reflective electrode, and an optical film. The light-transmissive electrode and the reflective electrode are respectively disposed at two opposite sides of the organic active layer, the optical film and the organic active layer are respectively disposed at two opposite sides of the light-transmissive electrode, and the optical film has an inner surface and an outer surface opposite to the inner surface. The transmittance of the optical film is higher than 90% when light enters the optical film from the outer surface. The reflectivity of the inner surface is higher than 10% when light enters the optical film from the inner surface. The haze of the optical film is higher than 90%.

In an embodiment of the disclosure, the optical film has a plurality of optical micro-structures located on the outer surface. For example, the optical micro-structures include scatters, micro-lenses, and micro-prisms.

In an embodiment of the disclosure, the organic active layer is a light-absorbing material, and the light-absorbing material may include GSID6040:[6,6]-phenyl-C71 butyric acid methyl ester ([70]PCBM), poly(3-hexylthiophene):[6,6]-phenyl-C 61-butyric acid methyl ester (P3HT:[60]PCBM), poly[2-methoxy-5-(30,70-dimethyloctyloxy)-1,4-phenylenevinylene]:[6,6]-phenyl-C61-butyricacidmethyl ester (MDMO-PPV:[60]PCBM), poly[2,6-(4,4-bis-(2-ethylhexyl)-4H-cyclopenta[2,1-b;3,4-b′]dithiophene)-alt-4,7-(2,1,3-benzothiadiazole)]:[6,6]-phenyl-C71 butyric acid methyl ester (PCPDTBT:[70]PCBM), and poly[4,8-bis-substituted-benzo[1,2-b:4,5-b′]dithiophene-2,6-diyl-alt-4-substituted-thieno [3,4-b]thio-phene-2,6-diyl]:[6,6]-phenyl-C71 butyric acid methyl ester (PBDTTT:[70]PCBM).

In an embodiment of the disclosure, the light-transmissive electrode includes a transparent conductive oxide electrode.

In an embodiment of the disclosure, the reflective electrode includes an aluminium electrode or a silver electrode.

In an embodiment of the disclosure, the OPV cell may further include a hole transport layer (HTL), disposed between the organic active layer and the light-transmissive electrode.

In an embodiment of the disclosure, the material of the HTL may include poly(3,4-ethylenedioxythiophene):poly(styrene sulfonate) (PEDOT:PSS).

In an embodiment of the disclosure, the OPV cell may further include a light-transmissive substrate, disposed between the light-transmissive electrode and the optical film.

Since an optical film is disposed at a light-incident side of the OPV cell in the disclosure, light entering the OPV cell is reflected many times and is absorbed by the active layer, such that the photoelectric conversion efficiency of the OPV cell is improved without increasing the thickness of the active layer.

To make the aforementioned and other objectives, features and advantages of the disclosure more comprehensible, several exemplary embodiments accompanied with figures are described in detail below to further describe the disclosure in details.

### BRIEF DESCRIPTION OF THE DRAWINGS

FIG. 1 is a schematic cross-sectional view of an OPV cell according to an embodiment of the disclosure;

FIG. 2A to FIG. 2C are schematic cross-sectional views of optical micro-structures according to an embodiment of the disclosure;

FIG. 3 is a schematic cross-sectional view of an OPV cell according to another embodiment of the disclosure; and

FIG. 4 is a view illustrating a relation between the quantum efficiency and the wavelength of an OPV cell with an optical film attached thereon and a relation between the quantum efficiency and the wavelength of an OPV cell without an optical film attached thereon.

### DETAILED DESCRIPTION OF DISCLOSED EMBODIMENTS

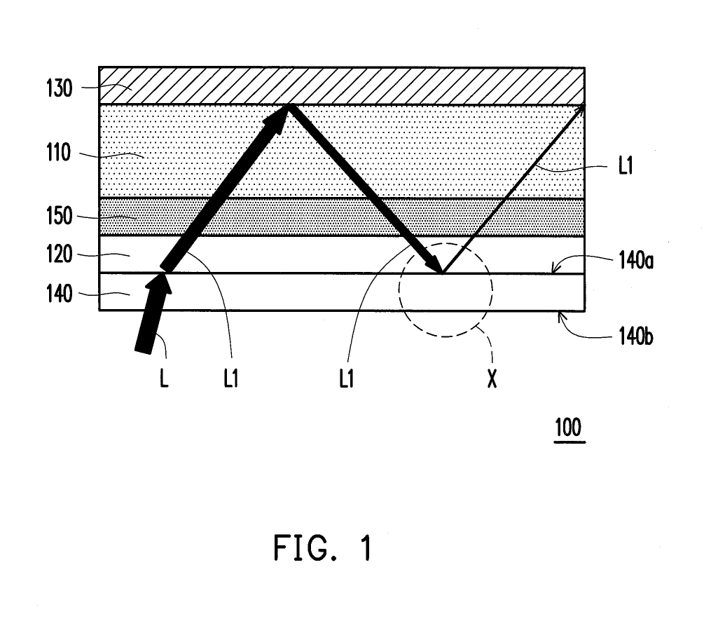

FIG. 1 is a schematic cross-sectional view of an OPV cell according to an embodiment of the disclosure. Referring to FIG. 1, an OPV cell 100 of this embodiment is applied to convert light L and L1 into electricity, and includes an organic active layer 110, a light-transmissive electrode 120, a reflective electrode 130, and an optical film 140. The light-transmissive electrode 120 and the reflective electrode 130 are respectively disposed at two opposite sides of the organic active layer 110, the optical film 140 and the organic active layer 110 are respectively disposed at two opposite sides of the light-transmissive electrode 120, and the optical film 140 has an inner surface 140a and an outer surface 140b opposite to the inner surface 140a. The transmittance of the optical film 140 is higher than 90% when light L enters the optical film from the outer surface 140b. The reflectivity of the inner surface 140a is higher than 10% when light L1 enters the optical film 140 from the inner surface 140a. The haze of the optical film 140 is higher than 90%.

In this embodiment, the material of the organic active layer 110 is, for example, GSID6040:[6,6]-phenyl-C71 butyric acid methyl ester ([70]PCBM) or other suitable organic materials, and the light-transmissive electrode 120 is, for example, a transparent conductive oxide electrode. For example, the material of the transparent conductive oxide electrode is, for example, indium tin oxide (ITO), indium zinc oxide (IZO), or other conductive materials having a high transmittance. Furthermore, the reflective electrode 130 is, for example, an aluminium electrode, a silver electrode, or other metal electrodes having a high reflectivity.

In view of the above, the OPV cell 100 of this embodiment may selectively include a HTL 150, disposed between the organic active layer 110 and the light-transmissive electrode 120. The HTL 150 improves the transmission efficiency of the hole in the OPV cell 100. For example, the material of the hole transport layer 150 includes poly(3,4-ethylenedioxythiophene):poly(styrene sulfonate) (PEDOT:PSS) or other suitable organic materials.

As shown in FIG. 1, the optical film 140 of this embodiment is disposed at a light-incident side of the OPV cell 100. Since the external light L may first pass through the optical film 140 before entering the organic active layer 110, the optical film 140 needs to have a high transmittance with respect to the external light L, and the high transmittance herein indicates a transmittance higher than or equal to 90%. Compared with the light L, the light L1 entering the organic active layer 110 may inevitably be attenuated slightly, and the light L1 may be reflected by the reflective electrode 130 and pass through the organic active layer 110 twice, so as to increase the possibility of being absorbed by the organic active layer 110, thereby improving the photoelectric conversion efficiency of the OPV cell 100. To utilize the light L1 reflected by the reflective electrode 130 more efficiently, the reflectivity of the light L1 of the inner surface 140a of the optical film 140 needs to be higher than 10%, such that part of the light L1 is further reflected back to the organic active layer 120, so as to be absorbed by the organic active layer 120. For example, the reflectivity of the light L1 of the inner surface 140a of the optical film 140 is in a range of 20-30%. Furthermore, the haze of the optical film 140 is, for example, 90%, 95%, or higher than 95%.

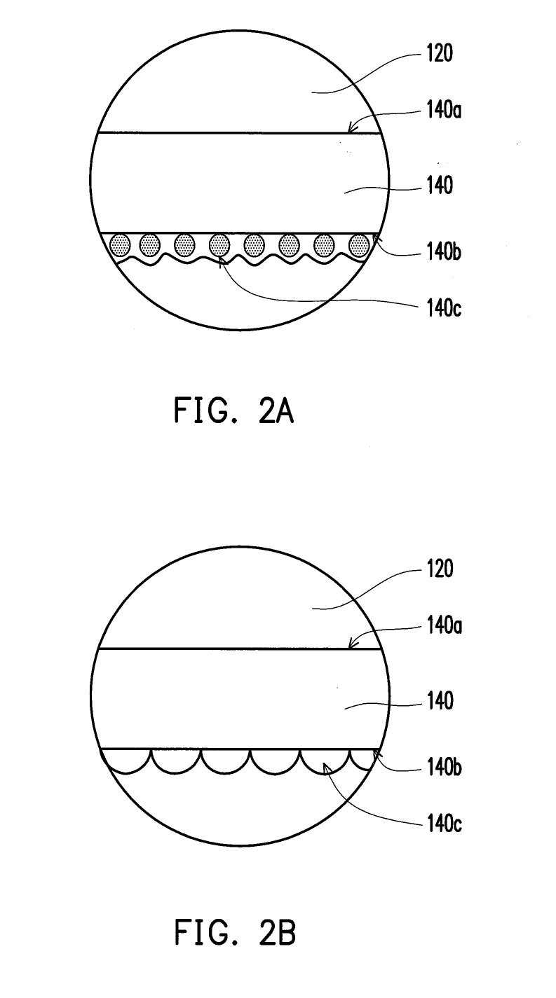

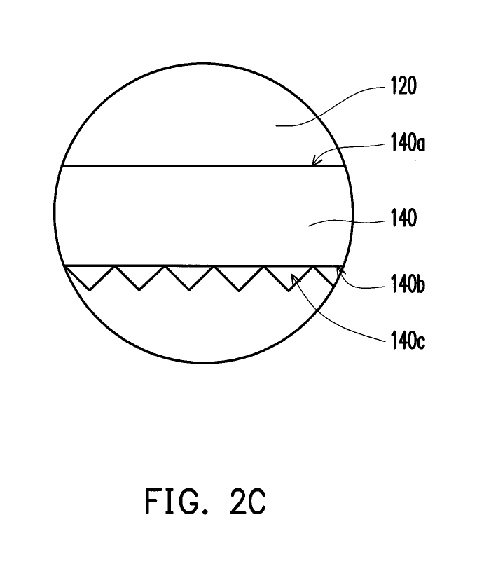

FIGS. 2A to 2C are schematic cross-sectional views of optical micro-structures according to an embodiment of the disclosure. Referring to FIGS. 2A to 2C, in order to make most of the light L to enter the OPV cell 100, in this embodiment, a plurality of optical micro-structures 140c may be fabricated on the outer surface 140b of the optical film 140. For example, the optical micro-structures 140c are scatters capable of scattering the light L, micro-lenses capable of modulating the propagating path of the light L, or micro-prisms capable of modulating the propagating path of the light L. Specifically, the optical film 140 is, for example, a diffusion plate, a micro-lens array optical film, or a prism sheet.

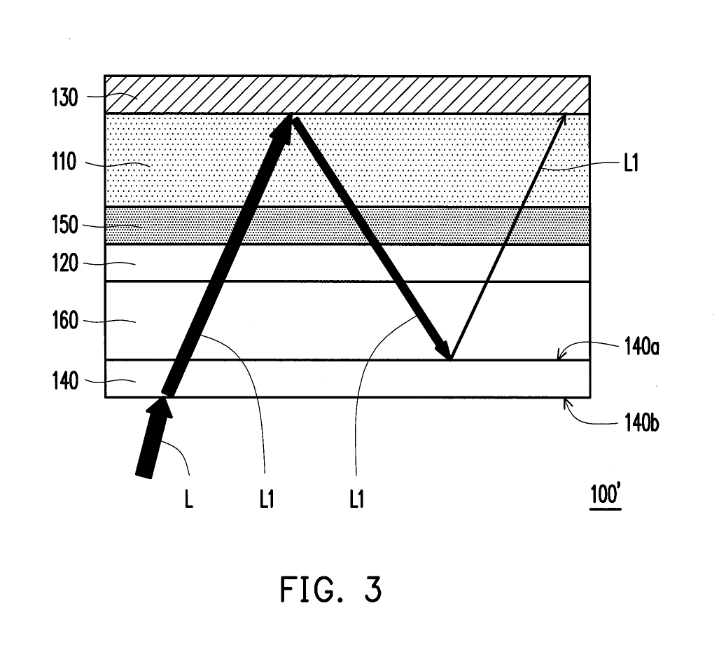

FIG. 3 is a schematic cross-sectional view of an OPV cell according to another embodiment of the disclosure. Referring to FIGS. 1 and 3, an OPV cell 100′ of this embodiment is similar to the OPV cell 100 in FIG. 1 except that the OPV cell 100′ of this embodiment may further include a light-transmissive substrate 160 disposed between the light-transmissive electrode 120 and the optical film 140.

Experimental Examples

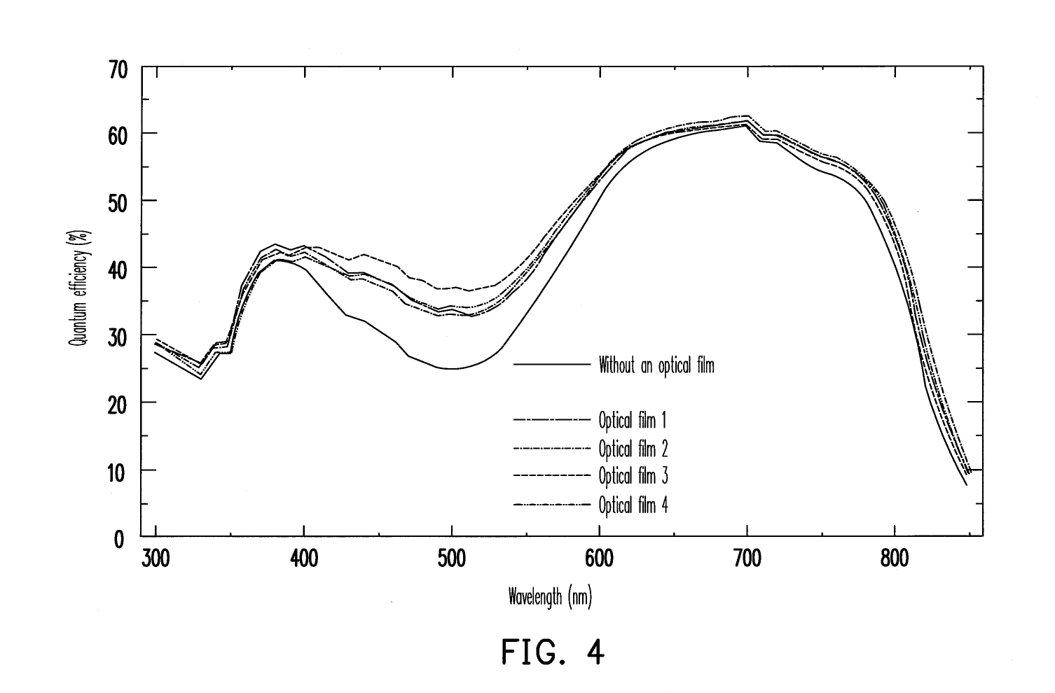

FIG. 4 is a view illustrating a relation between the quantum efficiency and the wavelength of an OPV cell with an optical film attached thereon and a relation between the quantum efficiency and the wavelength of an OPV cell without an optical film attached thereon. Referring to FIG. 4, this experimental example adopts the structure mentioned in FIG. 3, in which the thickness of the organic active layer is 70 nm, the material of the organic active layer is GSID6040:[6,6]-phenyl-C71 butyric acid methyl ester ([70]PCBM), the thickness of the HTL is 30 nm, the material of the HTL is poly(3,4-ethylenedioxythiophene):poly(styrene sulfonate) (PEDOT:PSS), and the light-transmissive substrate is a glass substrate.

It can be clearly known from FIG. 4 that, in the visible band (from 400 nm to 700 nm), different optical films improve the quantum efficiency of the OPV cell to different extents.

Table 1 lists optical parameters (transmittance, reflectivity of the inner surface, and haze) of different optical films (an optical film 1, an optical film 2, an optical film 3, and an optical film 4), and Table 2 lists short circuit current differences and gains of an OPV cell without an optical film attached thereon and an OPV cell with an optical film attached thereon.

TABLE 1

| | | Reflectivity of | |
|---|---|---|---|
| | Transmittance | the inner surface | Haze |
| Optical film 1 | 100% | 20% | 95% |
| Optical film 2 | 100% | 25% | 90% |
| Optical film 3 | 100% | 30% | >95% |
| Optical film 4 | 100% | 30% | 95% |

TABLE 2

| | Short circuit current | |
|---|---|---|
| | Jsc (mA/cm²) | Gain (%) |
| Without an optical film | 12.99 | — |
| Optical film 1 | 14.12 | 8.7 |
| Optical film 2 | 14.14 | 8.9 |
| Optical film 3 | 14.33 | 10.3 |
| Optical film 4 | 14.16 | 9.0 |

It can be know from Table 2, the short circuit current of the OPV cell with the optical film attached thereon is improved by about 10%.

Since an optical film is disposed at a light-incident side of the OPV cell in the disclosure, light entering and propagating within the OPV cell is reflected many times and is absorbed by the active layer, such that the photoelectric conversion efficiency of the OPV cell of the present invention is improved without increasing the thickness of the active layer.

It will be apparent to those skilled in the art that various modifications and variations can be made to the structure of the disclosed embodiments without departing from the scope or spirit of the disclosure. In view of the foregoing, it is intended that the disclosure cover modifications and variations of this disclosure provided they fall within the scope of the following claims and their equivalents.

What is claimed is:

1. An Organic Photovoltaic (OPV) cell for converting light into electricity, the OPV cell comprising:
an organic active layer;
a light-transmissive electrode;
a reflective electrode, wherein the light-transmissive electrode and the reflective electrode are respectively disposed at two opposite sides of the organic active layer; and
an optical film, wherein the optical film and the organic active layer are respectively disposed at two opposite sides of the light-transmissive electrode, the optical film has an inner surface and an outer surface opposite to the inner surface, the transmittance of the optical film is higher than 90% when light enters the optical film from the outer surface, the reflectivity of the inner surface is higher than 10% when light enters the optical film from the inner surface, and the haze of the optical film is higher than 90%.

2. The OPV cell according to claim 1, wherein the optical film has a plurality of optical micro-structures located on the outer surface.

3. The OPV cell according to claim 2, wherein the optical micro-structures comprise scatters.

4. The OPV cell according to claim 2, wherein the optical micro-structures comprise micro-lenses.

5. The OPV cell according to claim 2, wherein the optical micro-structures comprise micro-prisms.

6. The OPV cell according to claim 1, wherein a material of the organic active layer is a light-absorbing material, and the light-absorbing material comprises GSID6040:[6,6]-phenyl-C71 butyric acid methyl ester ([70]PCBM), poly(3-hexylthiophene):[6,6]-phenyl-C61-butyric acid methyl ester (P3HT:[60]PCBM), poly[2-methoxy-5-(30,70-dimethyloctyloxy)-1,4-phenylenevinylene]:[6,6]-phenyl-C61-butyricacidmethyl ester (MDMO-PPV:[60]PCBM), poly[2,6-(4,4-bis-(2-ethylhexyl)-4H-cyclopenta[2,1-b;3,4-b′]dithiophene)-alt-4,7-(2,1,3-benzothiadiazole)]:[6,6]-phenyl-C71 butyric acid methyl ester (PCPDTBT:[70]PCBM), or poly[4,8-bis-substituted-benzo[1,2-b′]dithiophene-2,6-diyl-alt-4-substituted-thieno [3,4-b]thio-phene-2,6-diyl]:[6,6]-phenyl-C71 butyric acid methyl ester (PBDTTT:[70]PCBM).

7. The OPV cell according to claim 1, wherein the light-transmissive electrode comprises a transparent conductive oxide electrode.

8. The OPV cell according to claim 1, wherein the reflective electrode comprises an aluminium electrode or a silver electrode.

9. The OPV cell according to claim 1, further comprising a hole transport layer (HTL) disposed between the organic active layer and the light-transmissive electrode.

10. The OPV cell according to claim 9, wherein a material of the HTL comprises poly(3,4-ethylenedioxythiophene):poly(styrene sulfonate) (PEDOT:PSS).

11. The OPV cell according to claim 1, further comprising a light-transmissive substrate disposed between the light-transmissive electrode and the optical film.

12. The OPV cell according to claim 1, wherein a transmittance of the optical film is higher than 90% when light enters the optical film from the outer surface and has a wavelength of about 555 nm.
